(19) United States
(12) Patent Application Publication
(10) Pub. No.: US 2023/0339070 A1
(43) Pub. Date: Oct. 26, 2023

(54) HIGH-PRECISION SUBSTRATE POLISHING SYSTEM

(71) Applicant: KCTECH CO., LTD., Gyeonggi-do (KR)

(72) Inventors: Ki Hyuk YANG, Gyeonggi-do (KR); Sang Jeong WOO, Gyeonggi-do (KR)

(73) Assignee: KCTECH CO., LTD., Gyeonggi-do (KR)

(21) Appl. No.: 18/136,834

(22) Filed: Apr. 19, 2023

(30) Foreign Application Priority Data
Apr. 22, 2022 (KR) 10-2022-0050070

(51) Int. Cl. B24B 49/14; B24B 49/04; B24B 7/04

(52) U.S. Cl. CPC B24B 49/14; B24B 49/045; B24B 7/04

(57) ABSTRACT

Provided is a high-precision substrate polishing system. An apparatus for polishing a substrate includes a platen on which a polishing pad is seated and which is rotatable, a substrate carrier configured to grip a substrate and rotatable on an upper side of the platen, an infrared sensor located inside the platen and configured to measure a temperature of the substrate, and a controller configured to determine a polishing state of the substrate using a value measured by the infrared sensor.

### CROSS-REFERENCE TO RELATED APPLICATIONS

This application claims the benefit of Korean Patent Application No. 10-2022-0050070 filed on Apr. 22, 2022, in the Korean Intellectual Property Office, the entire disclosure of which is incorporated herein by reference for all purposes.

### BACKGROUND

### 1. Field of the Invention

One or more embodiments relate to a high-precision substrate polishing system.

### 2. Description of the Related Art

In the manufacture of semiconductor elements, chemical mechanical polishing (CMP) operations including polishing, buffing, and cleaning are required. The semiconductor elements have a multilayer structure and transistor elements having a diffusion region are formed in a substrate layer. In the substrate layer, connecting metal lines are patterned and electrically connected to transistor elements forming functional elements. As is known, a patterned conductive layer is insulated from other conductive layers with an insulating material, such as silicon dioxide. As more metal layers and associated insulating layers are formed, the need to flatten the insulating material increases. Without flattening the insulating material, the manufacturing of additional metal layers becomes substantially more difficult because of the large variation in surface morphology. In addition, a metal line pattern is formed of an insulating material so that a metal CMP operation removes excess metal.

To reduce polishing errors and stabilize production in the polishing and planarization processes used in the middle of each process according to the miniaturization, refinement, and multi-layered wiring of semiconductor elements, the technology to detect a polishing end point is the most core technology. To detect the polishing end point, various sensor devices and the like are used. According to the related art, a method of analyzing reflected light reflected on a substrate using an optical sensor has been used. However, in the case of the optical sensor, since visible light is used as a light source, there is a problem in that a separate window for penetrating the polishing pad is required. In addition, the method using the optical sensor uses thin film interference and has a limitation that the method may be applied only to a transparent dielectric film.

The above description has been possessed or acquired by the inventor(s) in the course of conceiving the present disclosure and is not necessarily an art publicly known before the present application is filed.

### SUMMARY

Embodiments provide a method and an apparatus for polishing a substrate that may determine a polishing state by measuring a temperature of the substrate using an infrared sensor.

Embodiments provide a method and an apparatus for polishing a substrate that do not require a separate window and are not limited by a film of the substrate.

According to an aspect, there is provided an apparatus for polishing a substrate including a platen on which a polishing pad is seated and which is rotatable, a substrate carrier configured to grip a substrate and rotatable on an upper side of the platen, an infrared sensor located inside the platen and configured to measure a temperature of the substrate, and a controller configured to determine a polishing state of the substrate using a value measured by the infrared sensor.

The infrared sensor may be on a lower side of the polishing pad.

The infrared sensor may be configured to measure the temperature of the substrate by passing infrared rays through the polishing pad.

The controller may include a look-up table for a relationship between a polishing amount of the substrate and the temperature of the substrate.

The controller may be configured to determine a thickness of the substrate or a polishing end point according to the value measured by the infrared sensor, based on the look-up table.

The controller may be configured to terminate polishing when it is determined that the polishing end point has been reached.

The controller may include the look-up table for each thin film material of the substrate.

The apparatus may further include a corrector configured to correct the value measured by the infrared sensor.

According to another aspect, there is provided a method of polishing a substrate including polishing a substrate with a polishing pad, measuring a temperature of the substrate through an infrared sensor located inside a platen, and determining a polishing state of the substrate based on a pre-stored look-up table for a relationship between a polishing amount of the substrate and the temperature of the substrate.

The infrared sensor may be configured to measure the temperature of the substrate by passing infrared rays through the polishing pad.

The look-up table may be stored for each thin film material of the substrate.

The polishing state of the substrate may include information about a thickness of the substrate or a polishing end point.

The method may further include terminating polishing when it is determined that a polishing end point has been reached.

Additional aspects of embodiments will be set forth in part in the description which follows and, in part, will be apparent from the description, or may be learned by practice of the disclosure.

According to embodiments, a method and an apparatus for polishing a substrate may measure a temperature of a substrate using an infrared sensor and determine a polishing state of the substrate through the temperature of the substrate.

According to embodiments, a method and an apparatus for polishing a substrate do not require a separate window and may be applied to various films of the substrate without being restricted by the film of the substrate.

According to embodiments, an effect of a method and an apparatus for polishing a substrate is not limited to the above-mentioned effects and other unmentioned effects can be clearly understood from the following description by one of ordinary skill in the art.

### BRIEF DESCRIPTION OF THE DRAWINGS

These and/or other aspects, features, and advantages of the invention will become apparent and more readily appreciated from the following description of embodiments, taken in conjunction with the accompanying drawings of which:

FIG. 1 is a schematic perspective view illustrating a substrate polishing apparatus according to an embodiment;

FIG. 2 is a schematic cross-sectional view illustrating the substrate polishing apparatus according to an embodiment; and

FIG. 3 is a flowchart illustrating a substrate polishing method according to an embodiment.

### DETAILED DESCRIPTION

Hereinafter, embodiments will be described in detail with reference to the accompanying drawings. However, various alterations and modifications may be made to the embodiments. Here, the embodiments are not meant to be limited by the descriptions of the present disclosure. The embodiments should be understood to include all changes, equivalents, and replacements within the idea and the technical scope of the disclosure.

The terminology used herein is for the purpose of describing particular embodiments only and is not intended to be limiting. The singular forms “a,” “an,” and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which the embodiments belong. Terms, such as those defined in commonly used dictionaries, are to be interpreted as having a meaning that is consistent with their meaning in the context of the relevant art and the present disclosure, and are not to be interpreted in an idealized or overly formal sense unless expressly so defined herein.

When describing the embodiments with reference to the accompanying drawings, like reference numerals refer to like components and a repeated description related thereto will be omitted. In the description of embodiments, detailed description of well-known related structures or functions will be omitted when it is deemed that such description will cause ambiguous interpretation of the present disclosure.

In addition, terms such as first, second, A, B, (a), (b), and the like may be used to describe components of the embodiments. These terms are used only for the purpose of discriminating one constituent element from another constituent element, and the nature, the sequences, or the orders of the constituent elements are not limited by the terms. When one constituent element is described as being “connected”, “coupled”, or “attached” to another constituent element, it should be understood that one constituent element can be connected or attached directly to another constituent element, and an intervening constituent element can also be “connected”, “coupled”, or “attached” to the constituent elements.

The same name may be used to describe an element included in the examples described above and an element having a common function. Unless otherwise mentioned, the descriptions of the examples may be applicable to the following examples and thus, duplicated descriptions will be omitted for conciseness.

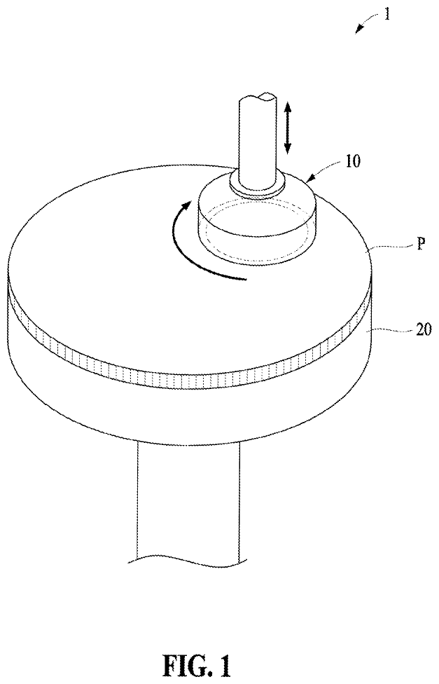

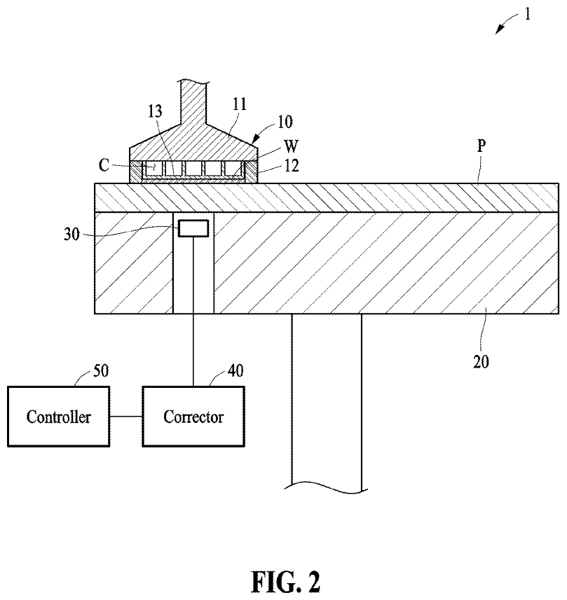

FIG. 1 is a schematic perspective view illustrating a substrate polishing apparatus according to an embodiment and FIG. 2 is a schematic side view illustrating the substrate polishing apparatus according to an embodiment.

Referring to FIGS. 1 and 2, a substrate polishing apparatus 1 according to an embodiment may be used for a chemical mechanical polishing (CMP) process of a substrate W.

In an embodiment, the substrate W may be a silicon wafer for manufacturing a semiconductor device. However, the type of the substrate W is not limited thereto. For example, the substrate W may include glass for flat panel display (FPD) devices, such as a liquid crystal display (LCD) or a plasma display panel (PDP).

In an embodiment, the substrate polishing apparatus 1 may polish the substrate W. The substrate polishing apparatus 1 may include a substrate carrier 10, a platen 20, an infrared sensor 30, a corrector 40, and a controller 50.

In an embodiment, the substrate carrier 10 may grip the substrate W. The substrate carrier 10 may chuck and grip the substrate W to be polished and may move the gripped substrate W to the upper portion of a polishing pad P. The substrate carrier 10 may perform polishing of the substrate W by contacting the substrate W transferred to the upper portion of the polishing pad P with the polishing pad P. By pressing the substrate W in contact with the polishing pad P, the substrate carrier 10 may adjust a degree of polishing of the substrate W by adjusting frictional force between the substrate W and the polishing pad P. The substrate carrier 10 may include a carrier head 11, a membrane 12, and a retainer ring 13.

In an embodiment, the carrier head 11 may adjust a location of the substrate W. The carrier head 11 may receive power from outside and rotate around an axis perpendicular to a surface of the polishing pad P. The substrate W gripped according to the rotation of the carrier head 11 may be polished while rotating in contact with the polishing pad P.

In an embodiment, the carrier head 11 may move the substrate W horizontally. For example, the carrier head 11 may translate in a first direction parallel to the surface of the polishing pad P and in a second direction perpendicular to the first direction. Through complex movement in the first and second directions, the carrier head 11 may move the substrate W on a plane parallel to the surface of the polishing pad P. As a result, the substrate W may be transferred to or removed from a polishing location according to the horizontal movement of the carrier head 11.

In an embodiment, the carrier head 11 may move the substrate W vertically with respect to the ground. The carrier head 11 may move vertically with respect to a supporter of the substrate W for chucking/dechucking of the substrate W or move vertically with respect to the polishing pad P for polishing the substrate W.

In an embodiment, the membrane 12 may be connected to the carrier head 11 and may form a pressure chamber C for applying pressure to the substrate W. The pressure on the substrate W may be adjusted according to a pressure change of the pressure chamber C formed by the membrane 12. For example, a degree to which the substrate W is pressed against the polishing pad P may increase through pressure rise of the pressure chamber C while the substrate W is in contact with the polishing pad P. The membrane 12 may include a bottom plate forming the bottom surface of the pressure chamber C and a flap forming a side wall of the pressure chamber C. A plurality of flaps may be formed to have different radii based on the center of the bottom plate of the pressure chamber C, and each pressure chamber C may be formed for each space between adjacent flaps. Different pressures may be applied to the pressure chambers C, and a portion of the substrate W corresponding to each pressure chamber C may be locally pressurized according to the pressure applied to each pressure chamber C. The shape, size and/or number of pressure chambers C shown in FIG. 2 are only an example and are not limited thereto.

In an embodiment, the retainer ring 13 may be connected to the carrier head 11 to wrap the circumference of the gripped substrate W. The retainer ring 13 may prevent the substrate W from separating from a gripped location. For example, the retainer ring 13 may support a side surface of the substrate W to prevent the substrate W from separating from the substrate carrier 10 due to vibration and/or friction generated during polishing of the substrate W.

In an embodiment, the polishing pad P may be seated on the platen 20. For example, the polishing pad P may be seated on the upper portion of the platen 20. The platen 20 may polish a polishing surface of the substrate W in contact with the polishing pad P while rotating around an axis.

In an embodiment, the infrared sensor 30 may be located inside the platen 20. For example, the infrared sensor 30 may be located inside the platen 20 so as to be on the lower side of the polishing pad P. For example, a space for the infrared sensor 30 to be fixedly located may be formed inside the platen 20. The infrared sensor 30 may measure a temperature of the substrate W by passing infrared rays through the polishing pad P. Since the infrared rays irradiated from the infrared sensor 30 may pass through the polishing pad P, a separate window may not be formed on the platen 20 and/or the polishing pad P. The infrared sensor 30 may measure a temperature of a thin film of the polishing surface of the substrate W. For example, as polishing progresses, a temperature of the polishing surface of the substrate W may rise due to physical friction with the polishing pad P and chemical reaction of a slurry. The infrared sensor 30 may measure the temperature of the polishing surface of the substrate W in a non-contact manner by measuring radiant energy generated from the polishing surface of the substrate W.

In an embodiment, the corrector 40 may correct a value measured by the infrared sensor 30. For example, the corrector 40 may include a filter that may remove noise from the measured value.

In an embodiment, the controller 50 may receive the value measured by the infrared sensor 30. For example, the value measured by the infrared sensor 30 may be in a state to be corrected by the corrector 40. The controller 50 may monitor a temperature change of the substrate W over time. The controller 50 may determine a polishing state of the substrate W using the value measured by the infrared sensor 30. The polishing state of the substrate W may include information about the thickness of the substrate W or a polishing end point.

In an embodiment, the controller 50 may include a look-up table for a relationship between a polishing amount of the substrate W and the temperature of the substrate W. The look-up table may be pre-stored in the controller 50. For example, the look-up table may be generated and stored by performing polishing on a test substrate of which a state is known. The look-up table may be generated and stored for each thin film material of the substrate W. For example, since each thin film material has a unique specific heat, a degree of temperature rise according to the polishing progress may be different depending on the thin film material.

Therefore, by generating and storing the look-up table for each thin film material, the substrate polishing apparatus 1 may be applied to various thin film materials without being restricted by types of thin film material.

In an embodiment, the controller 50 may determine the thickness of the substrate W or the polishing end point according to the value measured by the infrared sensor 30, based on the look-up table for the thin film being polished. For example, the controller 50 may search for a value corresponding to a currently measured temperature of the substrate W in the look-up table and may determine the thickness of the current substrate W and/or the polishing end point. The determination may be performed in real-time while polishing is being performed. The controller 50 may continue polishing until the polishing end point has been reached and may terminate the polishing when it is determined that the polishing end point has been reached.

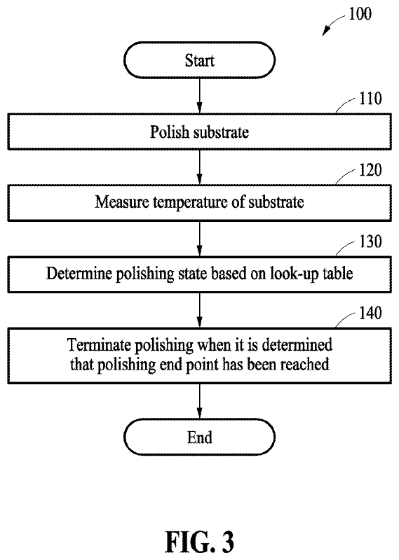

FIG. 3 is a flowchart illustrating a substrate polishing method according to an embodiment.

Referring to FIG. 3, a substrate polishing method 100 according to an embodiment may polish the substrate using the substrate polishing apparatus 1 according to FIGS. 1 and 2.

In an embodiment, the substrate polishing method 100 may include operation 110 of polishing a substrate, operation 120 of measuring a temperature of the substrate, operation 130 of determining a polishing state, and operation 140 of terminating polishing.

In an embodiment, operation 110 may be an operation of polishing the substrate with the polishing pad.

In an embodiment, operation 120 may be an operation of measuring the temperature of the substrate through the infrared sensor located inside the platen. Operation 120 may be performed simultaneously in real-time while operation 110 is being performed. The infrared sensor may measure the temperature of the substrate in a non-contact manner by passing infrared rays through the polishing pad.

In an embodiment, operation 130 may be an operation of determining the polishing state of the substrate based on the pre-stored look-up table for the relationship between the polishing amount of the substrate and the temperature of the substrate. The polishing state of the substrate may include information about the thickness of the substrate or the polishing end point. The look-up table may be pre-stored for each thin film material of the substrate. For example, the controller may search for the value corresponding to the currently measured temperature of the substrate in the look-up table for the thin film being polished and may determine the thickness of the current substrate and/or the polishing end point. Operation 130 may be performed in real-time while the polishing is being performed.

In an embodiment, operation 140 may be an operation of terminating the polishing when it is determined that the polishing end point has been reached. For example, when it is determined that the polishing end point has not been reached yet in operation 130, the polishing may continue and when it is determined that the polishing end point has been reached, the polishing may terminate.

The methods according to the examples may be recorded in non-transitory computer-readable media including program instructions to implement various operations of the examples. The media may also include, alone or in combination with the program instructions, data files, data structures, and the like. The program instructions recorded on the media may be those specially designed and constructed for the purposes of embodiments, or they may be of the kind well-known and available to those having skill in the computer software arts. Examples of non-transitory computer-readable media include magnetic media such as hard disks, floppy disks, and magnetic tape; optical media such as CD-ROM discs or DVDs; magneto-optical media such as optical discs; and hardware devices that are specially configured to store and perform program instructions, such as read-only memory (ROM), random access memory (RAM), flash memory, and the like. Examples of program instructions include both machine code, such as produced by a compiler, and files containing higher-level code that may be executed by the computer using an interpreter. The above-described devices may be configured to act as one or more software modules in order to perform the operations of the above-described embodiments, or vice versa.

The software may include a computer program, a piece of code, an instruction, or some combination thereof, to independently or collectively instruct or configure the processing device to operate as desired. Software and/or data may be embodied permanently or temporarily in any type of machine, component, physical or virtual equipment, computer storage medium or device, or in a propagated signal wave capable of providing instructions or data to or being interpreted by the processing device. The software also may be distributed over network-coupled computer systems so that the software is stored and executed in a distributed fashion. The software and data may be stored by one or more non-transitory computer-readable recording mediums.

While the embodiments are described with reference to drawings, it will be apparent to one of ordinary skill in the art that various alterations and modifications in form and details may be made in these embodiments without departing from the spirit and scope of the claims and their equivalents. For example, suitable results may be achieved if the described techniques are performed in a different order, and/or if components in a described system, architecture, device, or circuit are combined in a different manner, and/or replaced or supplemented by other components or their equivalents.

Accordingly, other implementations are within the scope of the following claims.

What is claimed is:

1. An apparatus for polishing a substrate, the apparatus comprising:
a platen on which a polishing pad is seated and which is rotatable;
a substrate carrier configured to grip a substrate and rotatable on an upper side of the platen;
an infrared sensor located inside the platen and configured to measure a temperature of the substrate; and
a controller configured to determine a polishing state of the substrate using a value measured by the infrared sensor.

2. The apparatus of claim 1, wherein the infrared sensor is on a lower side of the polishing pad.

3. The apparatus of claim 2, wherein the infrared sensor is configured to measure the temperature of the substrate by passing infrared rays through the polishing pad.

4. The apparatus of claim 1, wherein the controller comprises a look-up table for a relationship between a polishing amount of the substrate and the temperature of the substrate.

5. The apparatus of claim 4, wherein the controller is configured to determine a thickness of the substrate or a polishing end point according to the value measured by the infrared sensor, based on the look-up table.

6. The apparatus of claim 5, wherein the controller is configured to terminate polishing when it is determined that the polishing end point has been reached.

7. The apparatus of claim 4, wherein the controller comprises the look-up table for each thin film material of the substrate.

8. The apparatus of claim 1, further comprising:
a corrector configured to correct the value measured by the infrared sensor.

9. A method of polishing a substrate, the method comprising:
polishing a substrate with a polishing pad;
measuring a temperature of the substrate through an infrared sensor located inside a platen; and
determining a polishing state of the substrate based on a pre-stored look-up table for a relationship between a polishing amount of the substrate and the temperature of the substrate.

10. The method of claim 9, wherein the infrared sensor is configured to measure the temperature of the substrate by passing infrared rays through the polishing pad.

11. The method of claim 9, wherein the look-up table is stored for each thin film material of the substrate.

12. The method of claim 9, wherein the polishing state of the substrate comprises information about a thickness of the substrate or a polishing end point.

13. The method of claim 9, further comprising:
terminating polishing when it is determined that a polishing end point has been reached.
